(19) United States
(12) Patent Application Publication
(10) Pub. No.: US 2008/0245563 A1
(43) Pub. Date: Oct. 9, 2008

(54) Electromagnetic Wave Shielding Device

(75) Inventors: Nobuo Naito, Tokyo-To (JP); Fumihiro Arakawa, Tokyo-To (JP); Kazuhito Fujii, Tokyo-To (JP)

Correspondence Address: OLIFF & BERRIDGE, PLC, P.O. BOX 320850, ALEXANDRIA, VA, 22320-4850, US

(73) Assignee: DAI NIPPON PRINTING CO., LTD., Tokyo-To (JP)

(21) Appl. No.: 11/632,853

(22) PCT Filed: Jul. 25, 2005
(86) PCT No.: PCT/JP05/13596

§ 371 Date: Jan. 19, 2007

(30) Foreign Application Priority Data
Jul. 27, 2004 (JP) 2004-218047

(51) Int. Cl. H05K 9/00

(52) U.S. Cl. 174/392

(57) ABSTRACT

An electromagnetic wave shielding layer 1 comprises a transparent substrate 11, an adhesive layer 13 which is provided as needed, an electromagnetic wave shielding layer 15, and a transparent resin layer 17. The electromagnetic shielding layer 15 includes a mesh portion 103 facing a screen portion 100 of an image displaying device, a transparent resin layer anchoring portion 105 surrounding a periphery of the mesh portion 103 and including openings 105a having an opening ratio lower than that of openings 103a of the mesh portion 103, and a frame portion 107 surrounding an outer periphery of the transparent resin layer anchoring portion 105 and not having openings. The transparent resin layer 17 is provided such that it covers the surfaces of the mesh portion 103 and the transparent resin layer anchoring portion 105 and fills the openings 103a, 105a.

### BACKGROUND OF THE INVENTION

The present invention relates to a sheet adapted to shield electromagnetic waves, and particularly to an electromagnetic wave shielding material (electromagnetic shielding device) disposed on a front surface of an image displaying device (display), such as CRTs or PDPs, and adapted to shield electromagnetic waves generated from the image displaying device.

### FIELD OF THE INVENTION

As used herein, the term, “image displaying device”, means “display”, “CRT” means “Cathode Ray Tube (Braun tube)”, and “PDP” means “Plasma Display Panel”, and these terms are used as abbreviations, functional expressions, commonly known names or industrial terminologies.

### BACKGROUND ART

(Background Art) In recent years, with functional advance and increased utilization of electrical and electric equipments, the problems due to the electro magnetic interference (EMI) have been increased. A variety of image displaying devices are also generating sources of EMI. For example, the PDP is an assembly of a data electrode, a glass plate with a fluorescence layer, and a glass plate with a transparent electrode, from which, upon actuation, electromagnetic waves are generated in a great amount, thus requiring a shield of such electromagnetic waves. The shielding ability against the electromagnetic waves generated from a front surface of the PDP requires 30 dB or greater at 30 MHz to 1 GHz.

Electromagnetic noise is generally classified into conduction noise and radiation noise. Typically, a method of removing the conduction noise uses a noise filter. On the other hand, since the shield of radiation noise requires electromagnetically insulating a space of interest, there is a method of shielding the noise by providing a metallic case, inserting a metal plate between circuit boards, or wrapping a cable with a metal foil. While these methods are effective for shielding electromagnetic waves in relation to circuits or power source blocks, they cannot remove electromagnetic waves generated from a screen of an image displaying device, such as CRTs or PDPs, and the covering with a metal plate is not appropriate because it is not transparent.

For shielding electromagnetic waves to a screen of an image displaying device, various electromagnetic wave shielding materials have been proposed, produced and sold, which satisfy both the shielding ability against electromagnetic waves in a range of frequency bands from MHz to GHz and the transparency to the electromagnetic waves with frequency bands of the visible light. The most typical one is an electromagnetic wave shielding material (electromagnetic wave shielding device) which is constructed by laminating a mesh (a netlike or lattice structure) formed of a metal conductor on a transparent substrate made of a resin sheet. For the electromagnetic wave shielding material of this type, recently, there has been need for a material which is constructed as shown in FIG. 4 by coating a transparent resin on a metal mesh to fill the openings of the mesh with the resin so as to flatten uneven portions on the surface of the metal mesh.

Among recent image displaying devices, the PDP features a large-size screen, in which the size (external size) of an electromagnetic wave shielding material used for the front surface is, for example, 621×831 mm for the 37 type, 983×583 mm for the 42 type, or others for greater types. However, in the electromagnetic wave shielding sheet constructed by providing a transparent resin layer on a metal mesh, there has been found a problem that lifting or peeling may occur between the metal mesh and the transparent resin layer through all the processes from the production of the sheet to the assembly into an image displaying device as well as over a long period of the actual time of use. Namely, as shown in FIG. 4, a transparent resin layer 17 should cover in full the portion right over a mesh portion 103 facing a screen portion 100 of an image displaying device. In this case, the coating area of the transparent resin layer 17 should be larger than the area of the mesh portion 103 so that no portions lacking in the transparent resin layer 17 will exist right over the mesh portion 103 even if variation (misregistration) in the coated position should occur. Furthermore, it should be considered that the coated transparent resin tends to flow and further spread outward until it is cured. For this reason, actually, the transparent resin layer is further coated about 2 to 3 mm (corresponding to a portion B) over a frame portion (metal layer without openings) used for grounding and extending outwardly from the mesh portion 103. In the area of the mesh portion 103, due to the anchoring effect between the transparent resin layer and the metal mesh as well as their close chemical adherence to an adhesive layer 13, the transparent resin layer 17 and the metal mesh 103 can be readily and sufficiently adhered to each other. However, in the region of the frame portion 101, since the transparent resin layer 17 contacts with only a flat metal layer, neither the anchoring effect nor the chemical adherence to the adhesive layer can be expected. In addition, this area is an edge portion of a boundary between the transparent resin layer 17 and a shielding layer (metal layer) 15, thus the stress tends to be concentrated thereon. Therefore, possibility that peeling will occur at this portion becomes high.

Accordingly, for the electromagnetic wave shielding material for an image displaying device using a metal mesh, as a new challenge, in addition to an excellent electromagnetic wave shielding property and a proper transparency (transmittance of visible light), there exists another need for preventing lifting or peeling from occurring between the layers constituting the electromagnetic wave shield material during the production processes as well as over the period of actual time of use.

(Prior Art) In the past, in the electromagnetic wave shielding material constructed by forming a mesh portion using an electrically conductive material such as metals or the like on a surface of a transparent plastic substrate, those formed by coating a portion or the whole surface of the mesh portion with a transparent resin layer so as to flatten uneven portions on the mesh surface (e.g., see Patent Documents 1 and 2).

By filling recess portions of the openings of the mesh with a transparent resin layer so as to flatten the mesh surface, the aforementioned prior arts aim to obtain effects of preventing diffusion of light to be caused by bubbles remaining in the openings of the mesh, which bubbles being formed when an antireflection filter or the like is laminated on the mesh surface via an adhesive layer as well as to enhance the transparency by filling a rough surface of the adhesive material exposed in the openings. However, in fact, after having actually tried to produce the electromagnetic wave shield material based on these prior arts, we found that a new challenge to be further solved still remains. Namely, the electromagnetic wave shielding material for a screen of an image displaying device, usually for making a ground, has a metal frame region 101 not having openings at an outer periphery of the mesh portion. In this case, the transparent resin layer 17 is coated in an area larger than the mesh portion 103, so that the transparent resin layer 17 to be coated on the whole surface of the mesh portion 103 can securely cover the mesh portion 103 even if variation in the coated position should occur. In addition, because of spreading outward due to flowing of the resin layer 17 after coating, the edge portion B of the transparent resin layer 17 advances up to over the frame region 101 as shown in FIG. 4. However, the adhesive strength between the transparent resin layer 17 and the frame region 101 is significantly low, as compared to that strength of the transparent resin layer 17 over the mesh portion, because over the frame region 101 the transparent resin layer 17 adheres only to the flat and smooth metal surface. Furthermore, upon receiving external force, peeling stress will be concentrated on the edge portion B of the transparent resin layer. Accordingly, we found a problem that peeling between the transparent resin layer 7 and the frame region 101 occurs frequently at the edge portion B. It should be noted that in the aforementioned prior art documents there is no description or suggestion about prevention of lifting or peeling between the layers of the electromagnetic wave shielding material itself as well as about means of solving the problem.

Documents cited:

### Patent Document 1: Japanese Patent No. 3570420

### Patent Document 2: TOKUKAI No. 2002-311843, KOHO

### SUMMARY OF THE INVENTION

The present invention was made to solve the problems described above.

It is an object of the present invention to provide an electromagnetic wave shielding device which can provide an excellent electromagnetic wave shielding property, a proper transparency (transmittance of visible light), as well as, ability of preventing lifting or peeling between an electromagnetic wave shielding layer formed of an electrically conductive material and a transparent resin layer during the production processes as well as over the period of actual time of use, by providing a transparent resin layer anchoring portion surrounding a periphery of a mesh portion, and forming a transparent resin layer so as to fill and cover at least a portion of the transparent resin layer anchoring portion with the transparent resin layer.

The present invention is an electromagnetic wave shielding device disposed adjacent to the front surface of an image displaying device, comprising: a transparent substrate; an electromagnetic wave shielding layer provided on one surface of the transparent substrate and formed of an electrically conductive material; and a transparent resin layer provided on the electromagnetic wave shielding layer; wherein the electromagnetic wave shielding layer includes a mesh portion with a shape corresponding to a screen portion of the image displaying device including openings arranged in large numbers, a transparent resin layer anchoring portion surrounding the mesh portion, including openings arranged in large numbers and having an opening ratio lower than that of the openings of the mesh portion, and a flat frame portion surrounding the transparent resin layer anchoring portion and not having openings; and wherein the transparent resin layer is provided such that it extends over the surface of the mesh portion as well as over the surface of the transparent resin layer anchoring portion.

The present invention is the electromagnetic wave shielding device, wherein the transparent resin layer extends over the whole surface of the mesh portion as well as over the whole surface of the transparent resin layer anchoring portion and also covers an inner end portion of the frame portion.

The present invention is the electromagnetic wave shielding device, wherein the transparent resin layer extends over the whole surface of the mesh portion as well as over the whole surface of the transparent resin layer anchoring portion and terminates at the outer end portion of the transparent resin layer anchoring portion.

The present invention is the electromagnetic wave shielding device, wherein the transparent resin layer is provided to cover the whole surface of the mesh portion and an inner end portion of the transparent resin layer anchoring portion.

The present invention is the electromagnetic wave shielding device, wherein the transparent resin layer extends over the whole surface of the mesh portion up to a middle portion of the transparent resin layer anchoring portion, but does not cover the outer periphery of the transparent resin layer anchoring portion.

The present invention is the electromagnetic wave shielding device, wherein an adhesive layer is interposed between the transparent substrate and the electromagnetic wave shielding layer.

According to the present invention, an electromagnetic wave shielding device can be provided, which can exhibit an excellent electromagnetic wave shielding property, a proper transparency (transmittance of visible light), as well as, ability of preventing lifting or peeling between the electromagnetic wave shielding layer and the transparent resin layer during the production processes as well as over the period of actual time of use.

According to the present invention, an electromagnetic wave shielding material can be provided, in which the material to be used for the transparent resin layer can be reduced to a small amount, in which a share in forming the transparent resin layer can be accepted to some extent, in which lifting or peeling between the layers constituting the electromagnetic wave shielding material can be prevented during the production processes as well as over the period of actual time of use, and in which a lack of the transparent resin layer on the mesh portion facing a screen portion does not occur even in the presence of some variation in the coated position of the transparent resin layer.

According to the present invention, an electromagnetic wave shielding material can be provided, in which the transparent substrate and the electromagnetic wave shielding layer laminated via the adhesive layer can be firmly adhered to each other, and the adhesive layer exposed at the bottom faces of the mesh portion and the openings can also firmly adhere the transparent resin layer filling the openings to the laminated layers, so that the effect of preventing lifting or peeling between these layers constituting the electromagnetic wave shielding material during the production processes as well as over the period of actual time of use can be secured.

### BRIEF DESCRIPTION OF THE DRAWINGS

FIG. 1 is a plan view showing an electromagnetic wave shielding device according to the present invention.

FIGS. 2(A) and 2(B) are an enlarged plan view and an enlarged cross section of a portion A in FIG. 1, respectively.

FIGS. 3(A), 3(B) and 3(C) are cross sections of a key portion for explaining positions of a layer according to the present invention, respectively.

FIG. 4 is a cross section of a key portion for explaining a position of a conventional transparent resin layer.

### DETAILED DESCRIPTION OF THE INVENTION

Hereinafter, an embodiment of the present invention will be described in detail with reference to the drawings.

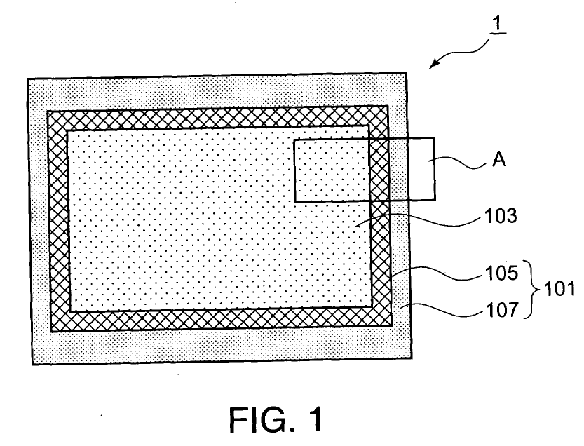

FIG. 1 is a plan view showing a first embodiment of the present invention.

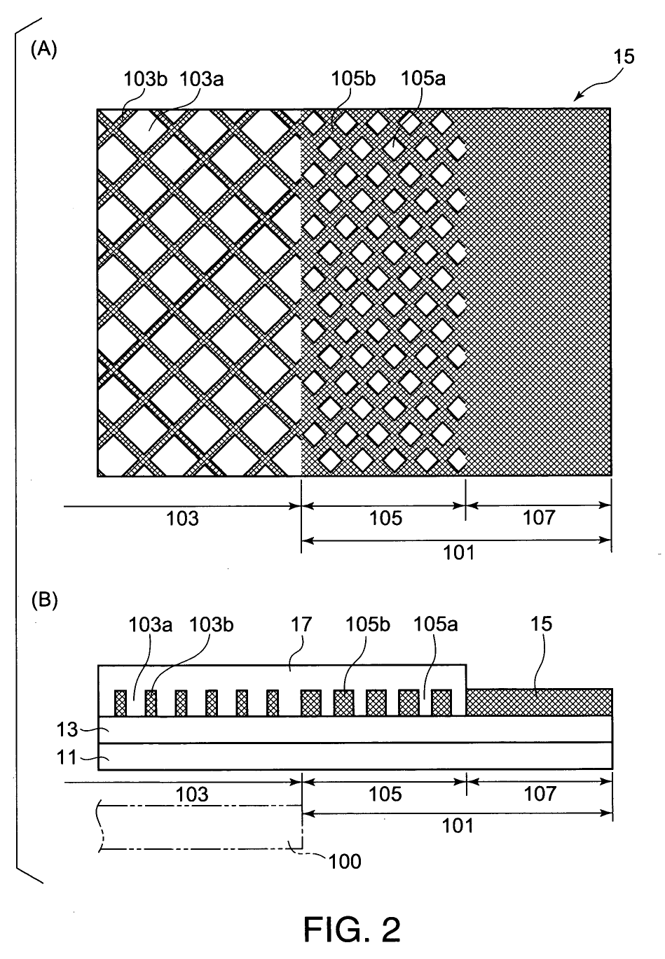

FIGS. 2(A) and 2(B) are an enlarged plan view and an enlarged cross section of a portion A in FIG. 1, respectively.

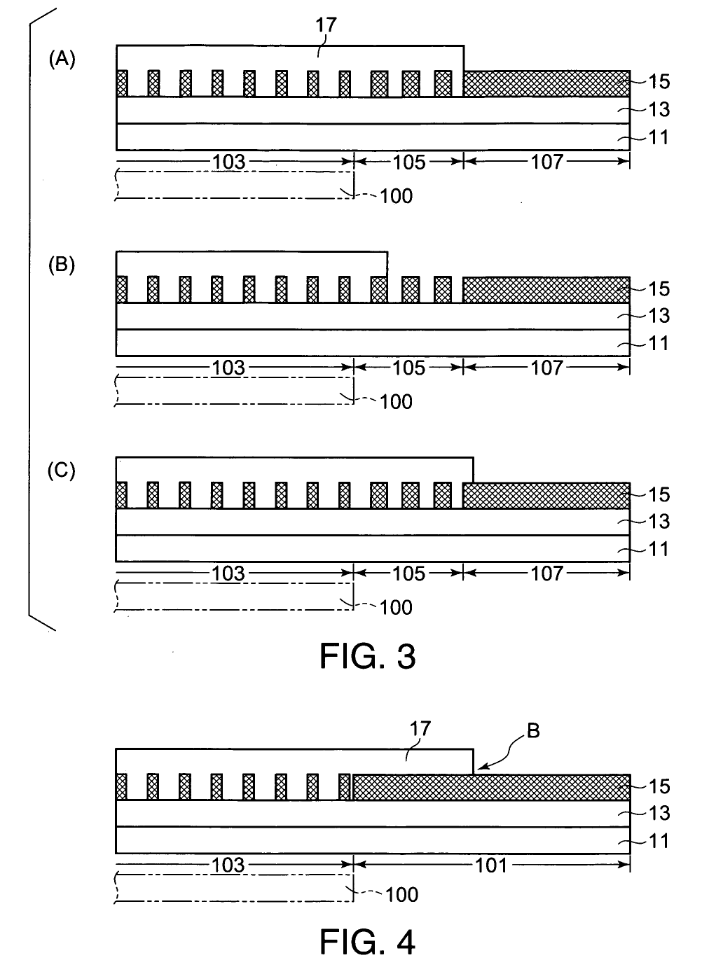

FIGS. 3(A), 3(B) and 3(C) are cross sections of essential portion for explaining positions of a layer according to the present invention, respectively.

(Electromagnetic Wave Shielding Material)

An electromagnetic wave shielding device (electromagnetic wave shielding material) according to the present invention will be described with reference to FIGS. 3(A), 3(B) and 3(C).

As shown in FIGS. 2(A) and 2(B), the electromagnetic wave shielding device (electromagnetic wave shielding material) 1 is disposed on the front surface of a screen 100 of an image displaying device, for example, a display panel (DPD) or the like, i.e., located adjacent to the screen on the side of observers. The electromagnetic wave shielding device 1 comprises a transparent substrate 11, an electromagnetic wave shielding layer 15 provided on one surface of the transparent substrate 11 through an adhesive layer 13 and formed of an electrically conductive material, and a transparent resin layer 17 provided on the electromagnetic wave shielding layer 15.

The electromagnetic shielding layer 15 includes a mesh portion 103 having a plurality of openings 103a arranged therein, a transparent resin layer anchoring portion 105 surrounding the mesh portion 103 and having openings (or holes) 105a, and a flat frame portion 107 surrounding the transparent resin layer anchoring portion 105 and not having openings. The mesh portion 103 is disposed facing the screen 100 of the image displaying device, such as a PDP, and has substantially the same shape as the screen 100.

In this case, the transparent resin layer anchoring portion 105 and the frame portion 107 constitute the frame region 101.

The mesh portion 103 includes openings 103a and line portions 103b surrounding these openings 103a, and the transparent resin layer anchoring portion 105 includes openings 105a and line portions 105b surrounding these openings 105a. The width of each line portion 105b of the transparent resin layer anchoring portion 105 is larger than that of each line portion 103b of the mesh portion 103, and the area of each opening 105a of the transparent resin anchoring portion 105 is smaller than that of each opening 103a of the mesh portion 103. The cycle of the pattern of line portions 103b is the same as that of the pattern of line portions 105b.

Therefore, the opening ratio of the openings 105a of the transparent resin layer anchoring portion 105 is smaller than the opening ratio of the openings 103a of the mesh portion 103.

Additionally, the frame portion 107 is connected to a ground in the case where the electromagnetic wave shielding device 1 is provided adjoining to the screen 100 of the image displaying device.

As showing in FIG. 2(B), the transparent resin layer 17 extends over the whole surface of the mesh portion 103 as well as over the whole surface of the transparent resin layer anchoring portion 105, while filling and covering the openings 103a, 105a. In this case, the transparent resin layer 17 terminates at an outer edge portion of the transparent resin layer anchoring portion 105.

Alternatively, the transparent resin layer 17 may extend up to a middle portion of the transparent resin layer anchoring portion 105, but may not cover the outer periphery of the transparent resin layer anchoring portion 105 (FIG. 3(B)).

Also, the transparent resin layer 17 may extend over the whole surface of the transparent resin layer anchoring portion 105 and cover the inner edge portion of the frame portion 107 not having openings (FIG. 3(C)).

Preferably, the transparent resin layer 17 terminates at the outer edge portion of the transparent resin layer anchoring portion 105 and not extending over the frame portion 107 (FIG. 3(A)). The openings (or holes) 105a of the transparent resin layer anchoring portion 105 may be formed to extend from the surface to the bottom face of the electromagnetic wave shielding layer 15, or formed into recesses such that each opening 105a terminates on the way of the depth through the electromagnetic wave shielding layer 15, rather than extending through the electromagnetic shielding layer 15. In either case, an adequate anchoring effect can be obtained. Since, the openings (or holes) 105a of the transparent resin layer anchoring portion 105 are located outside the screen 100 of an image displaying device and thus not required to make an image(s) to be seen through the openings, whether they extend through the transparent resin layer anchoring portion 105 or not has no relation to the function of the image displaying device itself.

For the electromagnetic wave shielding material 1 of the present invention, the materials and formation of each layer will now be described.

### (Transparent Substrate)

As the material of the transparent substrate 11, as long as satisfying the transparency, insulating properties, heat resistance and mechanical strength, for the conditions of use and production, various materials can be applied, and, for example, glasses and transparent resins can be used.

### (Glasses)

As the glass material, quarts glasses, borosilicate glasses, soda lime glasses or the like can be applied. Preferably, this material has a relatively low coefficient of thermal expansion, and is excellent in the dimensional stability and workability, and is an alkali-free glass which does not contain alkali ingredients, and can also be used as an electrode substrate for the image displaying device.

### (Transparent Resins)

As the transparent resin material, sheets, films or plates formed from a resin, including polyester resins, such as polyethylene terephthalates, polybutylene terephthalates, polyethylene naphthalates, terephthalic acid-isophthalic acid-ethylene glycol copolymers and terephthalic acid-cyclohexanedimethanol-ethylene glycol copolymers; polyamide resins, such as nylon 6; polyolefin resins, such as polypropylenes and polymethylpentenes; acryl resins, such as polymethylmethacrylates; styrene resins, such as polystyrenes and styrene-acrylonitrile copolymers; cellulose resins, such as triacetyl celluloses; imide resins; and polycarbonates can be applied.

The transparent substrate formed of the transparent resins as described above may comprises a copolymerized resin mainly containing the resins, or a mixed structure (including polymer alloys), or a laminated product composed of a plurality of layers. While the transparent substrate may be an oriented film or non-oriented film, for the purpose of increasing the strength, a monoaxially or biaxially oriented film is preferred. In the case where the transparent substrate is formed of the transparent resin, the thickness of the transparent substrate is usually about 12 to 1000 μm, preferably 100 to 500 μm, and the most preferably 100 to 500 μm. To the contrary, in the case where the transparent substrate is formed of the glass, the thickness is preferably about 1000 to 5000 μm. In either case, if the thickness is below the aforementioned range, the mechanical strength will be insufficient, causing a warp, sag or rupture, but if above the range, the properties become excessive to be wasteful in the cost.

Usually, polyester resin films formed from polyethylene terephthalates or polyethylene naphthalates or glasses are excellent in the transparency and heat resistance, thus being used as an appropriate material. Among them, polyethylene terephthalates are the most suitable especially in respect of being impervious to breaking, having light weights, and easiness of production. A higher transparency is advantageous, and the transmittance of visible light is preferably 80% or higher.

Prior to the application of an adhesive, the transparent substrate may be subjected to an adhesion facilitating treatment, such as a corona discharge, plasma treatment, ozone treatment, flaming treatment, primer (also referred to as an anchoring agent, adhesion enhancer or adhesion facilitating agent) coating, preheating, dust removing, vapor deposition or alkali treatment. Optionally, the resin film may be added with an ultraviolet ray absorbent, filler, plasticizer or antistatic agent.

### (Electromagnetic Wave Shielding Layer)

As the electromagnetic wave shielding layer 15 for shielding electromagnetic waves, though not limited in particular as good as the material has electric conductivity sufficient for shielding electromagnetic waves, typically, a layer or layers of a metal or metals having electric conductivity sufficient for adequately shielding electromagnetic waves, such as gold, silver, copper, iron, nickel, chromium, aluminum, can be included. The electromagnetic wave shielding layer may be formed by lamination of a metal foil preformed into a film as an independent layer on the transparent substrate via an adhesive layer, or by direct deposition of a metal layer with vapor deposition, sputtering or plating on the transparent substrate film. Instead of being formed with a single metal material, the metal foil or metal layer may be an alloy or a plurality of layers. As the metal foil, in the case of iron, low carbon steel, such as low carbon rimmed steel or low carbon aluminum-killed steel, Ni—Fe alloys, or invar alloys are preferred, while in the case of performing cathodic electrodeposition, copper or copper alloys are preferred due to facility of the electrodeposition. In particular, as a copper preformed into a film, i.e., a copper foil, a rolled copper foil or an electrolytically produced copper foil may be used, with the electrolytically produced copper foil being preferred in respect of the uniformity of thickness, adhesion properties to a blackened and/or chromate-treated layer, and possibility of forming the film thickness less than 10 μm. The thickness of the electrolytically produced copper foil is approximately 1 to 100μ, preferably 5 to 20 μm. If the thickness is below the range, the mesh forming process using the photolithography becomes easy, while increasing the electric resistance of the metal, thus impairing the electromagnetic wave shielding effect. To the contrary, if the thickness exceeds the range, a desired high-definition meshed shape cannot be obtained. As a result, the substantial opening ratio becomes low, thus lowering the transmittance of light, as well as compromising the visual angle and degrading the visibility of the image.

The surface roughness of the metal foil or metal layer is preferably 0.5 to 10 μm as defined by the Rz value. If it is below this range, mirror reflection of natural light will occur even after subjected to a blackening process, and as such degrading the visibility of the image. However, if it exceeds the range, upon coating an adhesive or resist on the surface, the material will not spread well over the whole surface, and bubbles tend to occur. It is noted that the surface roughness Rz is an average of values measured for 10 items in accordance with JIS-B0601 (1994 edition).

(Blackening and/or Anticorrosive Treatment)

To the electromagnetic wave shielding layer 15, a publicly known blackening treatment is provided at least on the side of observers of the mesh-like electrically conductive material in order to absorb extraneous light coming to the electromagnetic wave shielding material, and enhance the visibility of the image of the display, so as to improve the feeling of contrast. Alternately or additionally, a publicly known anticorrosive layer may be applied to the mesh-like electrically conductive material and/or the blackened surface in order to prevent elimination of the anticorrosive function and blackening effect or deformation.

### (Blackening Treatment)

The aim of the blackening treatment is only to make a predetermined face of the metal foil or metal layer be adequately roughened or blackened, various approaches can be applied to this treatment, including those for producing metals, metal oxides, metal sulfides, or metal alloys. In the case of iron, it is usual to form an oxide film (blackened film) consisting of Fe₃O₄ with a 1 to 2 μm thickness by exposing the surface of iron to a steam at a temperature of about 450 to 470° C. for 10 to 20 minutes. The oxide film (blackened film) obtained by a treatment using a chemical, such as concentrated nitric acid, may also be used. In the case of copper foils, it is preferred to select a cathodic electrodeposition, in which a copper foil is subjected to a cathode electrolytic treatment in an electrolytic solution containing sulfuric acid, copper sulfate and cobalt sulfate so as to make cationic particles be deposited onto the foil surface. The deposition of the cationic particles makes the surface be roughened as well as be blackened. As the cationic particles, while copper particles or alloy particles of copper and other metals can be used, particles of copper-cobalt alloys are preferred.

### (Alloy Particles)

While copper particles or alloy particles of copper and other metals can be used as the cationic particles, it is preferred to use particles of copper-cobalt alloys. When using the copper-cobalt alloy particles, the degree of blackening will be significantly enhanced, leading to better absorption of visible light. As the optical properties available to evaluate the visibility of the electromagnetic wave shielding sheets, the color tone is expressed using the calorimetric system (L*, a*, b*, ΔE*) in accordance with JIS-Z8729. In this case, lower L* (brightness of color) as well as lower absolute values of (a*) and (b*) (lower chroma) means that the electromagnetic wave shielding layer has a lower visibility, thus in turn leading to higher contrast of images, resulting in excellent visibility of the images. When using the copper-cobalt alloy particles, as compared to the case of copper particles alone, the values of (a*) and (b*) can be controlled to approximately zero (0).

It is preferred that the average particle diameter of the copper-cobalt alloy particles is in a range of 0.1 to 1 μm. If the particle diameter of the copper-cobalt alloy particles exceeds the range, the thickness of the electrically conductive layer will be insufficiently thin, leading to degradation of the workability including an increased tendency of the copper foil to be cut off or broken in the step of laminating the foil on the substrate 11, as well as to poor closeness in the appearance of aggregated particles and thus providing a markedly uneven surface. If the particle diameter is below the range, the roughening effect will be insufficient, as such degrading the visibility of images.

### (Anticorrosive Layer)

In order to prevent elimination of the anticorrosive function or blackening effect or deformation, it is preferred to provide a rust-preventive layer to at least the surface of the electrically conductive material, such as a metal, having been subjected to the blackening treatment. As the rust-preventive layer, oxides of nickel, zinc, and/or copper, or a chromate-treated layer can be used. Usually, it is preferred that the surface is subjected to zinc plating and then to a chromate treatment. The formation of oxides of nickel, zinc and/or copper may use a publicly known method, and the thickness of the formed film is approximately 0.001 to 1 μm, preferably 0.001 to 0.1 μm.

### (Chromate Treatment)

The chromate treatment includes coating a chromate treating liquid on a material to be treated. As the coating method, roll coating, curtain coating, squeeze coating, static atomization and dipping can be mentioned, in which the coated material can be directly dried without being washed with water. When only one side is subjected to the chromate treatment, the roll coating is employed for the one side coating, and when both sides is treated, the dipping may be selected. As the chromate treating liquid, an aqueous solution containing 3 g/l of CrO₂ is usually used. In addition, a chromate treating liquid prepared by adding different hydroxycarboxylic acid compounds to an aqueous chromic anhydride solution for reducing a part of hexavalent chromium to trivalent chromium can also be used. Depending on the amount of attachment of the hexavalent chromium, coloring to be light yellow to yellowish brown can be found. However, trivalent chromium is colorless. Accordingly, by controlling the amounts of the trivalent chromium and the hexavalent chromium, practically unquestionable transparency can be obtained. As the hydroxycarboxylic acid compounds, tartaric acid, malonic acid, citric acid, lactic acid, glycolic acid, glyceric acid, tropic acid, benzilic acid, hydroxyvaleric acid can be used alone or in combination with others. The reducing ability varies with the compounds, the addition amount is determined while monitoring the reduction to the trivalent chromium. Specifically, ALSURF 1000 (trade name of a chromate treating agent produced by Nippon Paint Co., Ltd.) and PM-284 (trade name of a chromate treating agent produced by Nippon Percarizing Co., Ltd.) can be mentioned. The chromate treatment can further enhance the effect of the blackening treatment.

To enhance the contrast and improve the visibility of images of the display, the blackening treatment and the anticorrosive layer have only to be provided at least on the side of observers. However, the blackening treatment and the anticorrosive layer may also be provided on the other side, i.e., on the side of the display surface. In this way, stray light occurring from the display can be suppressed, thus further enhancing the visibility of images.

### (Lamination)

As the method of laminating the substrate 11 and the electromagnetic wave shielding layer 15, a method, referred to as a dry lamination method by those skilled in the art, of laminating these layers via the adhesive layer 13 or a method of directly laminating the shielding layer 15 on the transparent substrate 11 by a plating technology without using the adhesive layer therebetween can be employed. As the plating technology, a publidy known plating method for subjecting the substrate 11 to an electrolytic plating or non-electrolytic plating can be utilized.

### (Dry Lamination)

The dry lamination is a method of laminating two types of materials together, comprising coating an adhesive agent dispersed or dissolved in a solvent on a material, using, for example, roll coating, reverse roll coating, gravure coating or the like, such that a film thickness after dried will be approximately 0.1 to 20 μm (dried state), preferably 1 to 10 μm, drying the solvent or the like, and immediately after forming the adhesive layer, laminating a corresponding substrate on the adhesive layer, followed by curing the adhesive material through aging for several hours to several days at 30 to 80° C. The adhesive layer employed in the dry lamination method may be a thermosetting resin, or an ionizing radiation curable resin which is cured by an ionizing radiation such as ultraviolet lays or electron beams. Specifically, as the adhesive agent composed of a thermosetting resin, two-part curable urethane-type adhesives, acryl-type adhesives, rubber-type adhesives and the like can be employed, with the two-part curable urethane-type adhesives being preferred. The two-part curable urethane-type adhesive can be cured by reaction of a polyfunctional polyol and a polyfunctional isocyanate. As the polyfunctional polyol, polyester polyols, acryl polyols, polyether polyols can be utilized. As the polyfunctional isocyanate, torilene-diisocyanate, xylylene-diisocyanate, hexamethylene-diisocyanate, isophorone-diisocyanate or addition products or polymers thereof can be used.

### (Mesh)

First, a mesh is formed in the electromagnetic wave shielding layer 15 not having openings, which is produced as described above. This mesh includes the mesh portion 103 facing the screen 100 of an image displaying device and the transparent resin layer anchoring portion 105 surrounding the periphery of the mesh portion 103. As the method of producing the mesh, the photolithography method can be employed.

### (Photolithography)

An electromagnetic wave shielding layer with a mesh-like pattern is formed by providing a resist layer into a mesh-like pattern on the surface of the electromagnetic wave shielding layer 15, etching to remove the electrically conductive layer corresponding to the portions not covered with the resist layer, followed by removing the resist layer. As shown in a plan view of FIG. 1, the electromagnetic wave shielding layer 15 includes, in succession, from its inside to outside, the mesh portion 103, the transparent resin layer anchoring portion 105 and the frame portion 107 not having openings. As shown in an enlarged plan view of FIG. 2(A) and an enlarged cross section of FIG. 2(B), the mesh portion 103 and the transparent resin layer anchoring portion 105 include the plurality of openings 103a, 105a surrounded by the line portions 103b, 105b, respectively, while in the frame portion 17 not having openings, the whole surface of the metal layer remains untreated.

Preferably, similar to the lamination method, the photolithography method is also performed such that the articles to be processed is moved in succession in a belt-like form and then wound in a roll-like shape. In this case, the laminated product of the transparent substrate 11 and the electromagnetic wave shielding layer 15 is carried successively or intermittently, while being subjected to masking, etching, resist releasing, with the laminated product being stretched without looseness. The masking is performed, for example, by coating a photosensitive resist on the electromagnetic wave shielding layer (electrically conductive layer), drying and then exposing it to light using a photo-mask with a predetermined pattern (of the line portions of the mesh and the frame portion), developing the exposed material with water, followed by hardening and then baking the so formed film. The resist coating is carried out by carrying the wound roll-like or belt-like laminated product successively or intermittently, while subjecting the surface of the electromagnetic shielding layer to dipping, curtain coating, flowing irrigation or the like with a resist of casein, PVA, gelatin or the like. Rather than application of the resist by coating, a dry film resist may be used, resulting in enhancement of the workability. Usually, in case of the casein resist, baking may be performed at 200 to 300° C., though it is preferred that the baking is carried out at a low temperature as low as possible, for example, at 100° C. or lower, to prevent a warp of the laminated body.

### (Etching)

The etching is performed after the masking process. As the etching solution used for the etching of the present invention where etching treatments are conducted in succession, the solution of ferric chloride or cupric chloride is preferred because of its facility of recycling use. The etching can be performed in an essentially the same process of producing shadow masks used for Braun tubes of color TVs, in which a belt-like and continuous thin plate of a steel material, especially having a thickness of 20 to 80 μm, is etched. Namely, an existing facility for producing the shadow masks can be applied to the etching, thus enabling to perform continuous treatments from masking to etching, thereby significantly enhancing the production efficiency. After the etching, the treated articles may be washed with water, subjected to resist releasing using an alkali solution, and then dried.

### (Mesh Portion)

The mesh portion 103 is a region surrounded by the frame region 101 including the transparent resin layer anchoring portion 105 and the frame portion 107. The mesh portion 103 includes the plurality of openings 103a surrounded by the line portions 103b. The shape of each opening 103a (of the mesh pattern) is not particularly limited to the shape shown, but may be, for example, polygons including triangles such as equilateral triangles, quadrilaterals such as squares, rectangles, rhomb and trapezoids, hexagons, circles, ellipses or the like. These openings 103a constitute a mesh with only one type of the shape or in combination of multiple types of the shapes. Due to the opening ratio and the invisibility of the mesh, the line width is 25 μm or less, preferably 20 μm or less, and it is preferred that the line interval (line pitch) is 150 μm or greater, preferably 200 μm or greater, based on the transmittance of light. In this case, the opening ratio is approximately 85 to 95%. The bias angle (angle formed by the line portions of the mesh and the sides of the electromagnetic wave shielding material) may be suitably selected to avoid a moiré pattern in view of the picture elements of the display and light emitting properties.

### (Transparent Resin Layer Anchoring Portion)

The mesh pattern of the transparent resin layer anchoring portion may have an opening ratio lower than that of the mesh portion 103. The term “opening ratio”, as used herein, means a ratio of the total area of the openings in a predetermined region (each of the mesh portion 103, transparent resin layer anchoring portion 105 or frame portion 107 not having openings) relative to the whole surface area of the electromagnetic wave shielding layer 15. In the transparent resin layer anchoring portion 105, openings are provided to anchor the periphery of the transparent resin layer 17 to the electromagnetic wave shielding layer 15. In this case, it is not necessary to form the openings with a size as large as the openings of the mesh portion 103 intended to pass the image light therethrough. However, if the opening ratio is discontinuously changed from a larger one to zero (0) at the boundary between the mesh portion 103 and the frame portion 107, stress will be concentrated in the vicinity of the boundary, leading to high tendency of rupture and breakage. Therefore, the opening ratio of the openings 105a in the transparent resin layer anchoring portion 105 is adjusted to be lower (or smaller) than the opening ratio of the openings 103a in the mesh portion 103. In this way, by adjusting the opening ratios to be reduced gradually from the mesh portion 103, transparent resin layer anchoring portion 105 to frame. portion 107 not having openings, while not affecting the quality of images to be displayed, the peripheral portion becomes impervious to breaking or rupturing even if an external force or deforming effect is applied to the electromagnetic wave shielding material.

While the shapes (mesh patterns) of the openings 103a, 105a may be similar patterns including a plurality of the same rectangles (FIG. 2(A), they are not limited to this shape in particular, but may be, for example, polygons including triangles such as equilateral triangles, quadrilaterals such as squares, rectangles, rhomb and trapezoids, and hexagons, circles, ellipses or the like. In the transparent resin layer anchoring portion 105, the area of each opening 105a may be adjusted to be smaller than the opening 103a in the mesh portion 103, the cycle of arrangement of the openings 105a may be adjusted larger than that of the openings 103a, or both the two adjustments may be combined to achieve a desired lower opening ratio. It should be noted that the shape of each opening 105a in the transparent resin layer anchoring portion 105 may be the same as or different from the shape of each opening 103a of the mesh portion 103.

Since it is not necessary that the transparent resin layer anchoring portion 105 can transmit image light from the image displaying device, it is not necessary for the openings 105a to be formed to extend through the electrically conductive material layer 15, and as such they may be recesses not extending through the layer 15. Selection of the shape of these recesses is an option as long as they can exhibit a desired anchoring effect.

More preferably, the opening ratio of the mesh pattern of the transparent resin layer anchoring portion 105 is gradually decreased as one moves from the portion contacting the mesh portion 103 toward the peripheral frame portion 107 not having openings, i.e., in a fashion of the so called gradation. In the conventional structure, since the rigidity is changed discontinuously at the boundary between the mesh portion 103 and the frame region 101, stress tends to be concentrated on the boundary over the whole process including the production step of the electromagnetic wave shielding material, and the incorporation and assembly of the material into a display, leading to high tendency of rupture, breakage or disconnection as well as to degrading handling properties, thus wasting expensive components. In accordance with the mesh pattern having the gradation as described above, even in the case of the electromagnetic wave shielding material for large size PDPs, no defects such as breakage or the like will occur over the whole process from the production of the material to its assembly into a device, thus providing excellent handling properties.

While a mask for the mesh pattern comprises a combination of a plurality of patterns, this mask can be readily manufactured using an image processing device. Also, this manufacturing process is easy, thus not leading to increase of the cost.

### (Smoothing and Improvement in Transparency)

The function of the transparent resin layer 17 is to smooth and make the mesh portion transparent. Namely, once the mesh portion 103 and the transparent resin layer anchoring portion 105 are formed, the line portions 103b, 105b have a thickness of the electromagnetic wave shielding layer 15, while the materials corresponding to the openings 103a, 105a are removed to make hollow portions or recesses, thus forming the electromagnetic shielding layer 15 including an uneven surface. In the case where an adhesive agent (or cohesive agent) is coated in the subsequent step, the uneven shape of the surface is flattened by adhesive agent. However, if the electromagnetic wave shielding layer 15 is attached onto the display immediately after the formation of the openings 103a, 105a, the workability will be very poor because of the uneven shape still remaining exposed. Therefore, the transparent resin layer 17 is used for smoothing the recesses in the uneven surface. Should the transparent resin layer 17 be missing, the transparent substrate 11 or the adhesive layer 13 would be exposed at the bottom face of the openings, the transparency of the transparent substrate 11 or the adhesive layer 13, especially, of the bottom surface of the adhesive layer 13 would be very poor because of diffuse reflection due to an uneven shape to be created by transfer of the uneven shape of the electromagnetic wave shielding layer 15. However, if the uneven shape is covered with the transparent resin layer 17, the diffuse reflection can be controlled, thus securely enhancing the transparency.

For smoothing, the transparent resin is applied to fill the recesses of the uneven shape. In this case, if the resin is not fully filled in every corner of each recess, bubbles will remain and the transparency will be degraded. Accordingly, the formation of the transparent resin layer 17 is performed by coating the resin layer material at a low viscosity using an appropriate solvent and then drying by vaporizing the solvent, or otherwise by coating the material together with deaeration. The term “smoothing”, as used herein, means to obtain smoothness flatness such that the displayed image will not be distorted, and haze due to light scattering will not occur. However, as far as the distortion of the display image and haze does not occur, the presence of a finely uneven shape (matted shape) in the flattened surface can be accepted in order to prevent air or bubbles from remaining between layers of the electromagnetic wave shielding materials when the surface blocking materials or electromagnetic wave shielding materials are rolled or stacked. Based on a macroscopic scale as large as the cycle of the mesh portion, the smoothing and transparency effects can be provided to the resultant smoothed surface, while based on a microscopic scale, as compared to the cycle of the mesh portion, finely uneven portions may be formed on the flattened surface locally overlapping one another to prevent air from being entrained upon rolling.

### (Transparent Resin Layer)

The transparent resin layer 17 may have a high transparency and a good adhesiveness to the electrically conductive mesh material as well as a good adhesiveness to the adhesive agent of the subsequent step. However, the presence of projections, recesses or unevenness on the surface of the transparent resin layer 17 is not preferred because if they exist thereon, a moiré pattern, interference fringes, Newton rings will occur when the layer 17 is applied to the display surface. An exemplary preferred method includes the steps of coating a resin, such as a thermosetting resin or ionizing radiation curable resin, into a desired pattern using a publicly known intermittent die coating method, laminating a releasing base material having an excellent flatness and a releasing ability on the coated material, followed by curing the coated resin with heat or ultraviolet rays, then removing the releasing base material. As a result, the flatness of the releasing base material is transferred to the surface of the transparent resin layer 17, thus forming a flat and smooth surface.

### (Ionizing Radiation Curable Resin)

The resin used for the transparent resin layer 17 is not limited in particular, and various natural or synthetic resins may be used therefor. While the curing type of the coated resin may include thermosetting resins, ionizing radiation curable resins or the like, acryl-type ultraviolet curing resins are preferred in view of the resin durability, coating ability, easiness to flatten, flatness, etc. The ionizing radiation curable resin mainly contains oligomers and/or monomers having functional groups which can be polymerized, without an initiator or with aid of an initiator, by irradiation of an ionizing radiation curable resin such as an ultraviolet ray or electron beam, and forms a cured product of the resin or components thereof by polymerization of the oligomers and/or monomers.

As the oligomers or monomers which constitute the ionizing radiation curable resin, those containing an ethylenically unsaturated double bond, such as an acryloil group, methacryloil group, methacryloiloxy group or the like and having the ability of radical polymerization may be used. However, other than those materials, various oligomers and/or monomers having the ability of photo-cationic polymerization, such as epoxy-group-containing compounds, may also be used.

### (Ionizing Radiation)

The term “ionizing radiation”, means, among electromagnetic waves and charged particle beams, those having an energy quantum able to polymerize or crosslink molecules, and ultraviolet rays or electron beams are usually used as the ionizing radiation. In the case of ultraviolet rays, a high pressure mercury lamp, low and high pressure mercury lamp, metal halide lamp, carbon arc, black light lamp or the like can be used as an radiation device (radiation source). Preferably, the energy of the ultraviolet ray (wavelength) is approximately 190 to 450 nm, and the radiation dose is approximately 50 to 1000 mJ/cm². In the case of electron beams, as the radiation device (radiation source), various electron beam accelerators, such as the cockloft warton type, van de Graaff type, resonance transformer type, insulation core transformer type or linear type, dynamitron type and high-frequency type can be used. Preferably, the energy of the electron beam is 70 to 1000 keV, preferably approximately 100 to 300 keV, and the radiation dose is approximately 0.5 to 30 Mrad. It is noted that in the case of the curing using an electron beam, the polymerization initiator may not be added to the ionizing radiation curable resin composition.

### (Coating Position of Transparent Resin Layer)

The coating position of transparent resin layer 17 is important. Essentially, the coating position of the transparent resin layer 17 is formed such that as shown in FIG. 3(A), the transparent resin layer 17 covers a region from the mesh portion 103 to the transparent resin layer anchoring portion 105 and fills the openings 103a, 105a. In this case, however, while the transparent resin layer 17 may cover all of the openings 103a, 105a, it may not extend over the frame portion 107 not having openings. Therefore, high precision in the positional control upon coating should be required, thus significantly increasing the difficulty of the process. To address this problem, as shown in FIG. 3(B), the coating is adjusted such that the transparent resin layer 17 only covers and fills up to a certain inner periphery of the openings 105a of the transparent resin layer anchoring portion 105, with the other openings 105a located in the outer periphery of the transparent resin layer anchoring portion 105 being left uncovered and unfilled. In this way, even if variation in the coating position of the transparent resin layer occurs in the lateral or transverse direction, it is possible to prevent the edge portion of the transparent resin layer 17 from being excessively back on the mesh portion 103 or extending over the frame portion 107. As show in FIG. 3(C), even in the case where the transparent resin layer 17 is formed covering the region from the mesh portion 103 to the transparent resin layer anchoring portion 105 and filling the openings 105a as well as extending some distance over the frame portion 107 not having openings, as long as the distance is less than approximately three cycles (three pitches) of the openings 105a, preferably less than one cycle (one pitch), the peel preventing effect between the transparent resin layer 17 and the electromagnetic wave shielding layer 17 can be ensured, thus still obtaining the benefit of the present invention.

FIG. 4 is a cross section of a key portion for explaining a position of a conventional transparent resin layer.

The coating position of the conventional transparent resin layer 17 is as shown in FIG. 4. Namely, the openings 103a of the mesh portion 103 facing the screen portion are covered with the transparent resin layer 17. Since there is no transparent resin layer anchoring portion, the transparent resin layer 17 extends a distance of about 2 to 3 mm or more (corresponding to 10 cycles or more (10 pitches or more) of the mesh openings) over the frame region (or frame portion) 101 not having openings such that the extending distance can securely compensate for variation of the coating position which usually fluctuates within a range of about 2 to 3 mm. In this case, the adhesiveness between the transparent resin layer 17 and the frame portion 101 is lower than that between the transparent resin layer 17 and the adhesive layer 13 or the transparent substrate 11. Therefore, if the transparent resin layer 17 covers the frame region 101 in a greater extent, lifting or peeling sometimes has occurred between the transparent resin layer and the electromagnetic wave shielding layer due to effect of external force to be applied to this portion over the whole process from the production step of the electromagnetic wave shielding material 1 to the step of assembling the material into a display as well as due to stress to be caused by difference between expansion ratios of the respective layers upon periodical expansion and contraction of the substrate due to undergoing warming and cooling and repetitions of moisture absorption and desorption cycles over a long period of the actual time of use. Moreover, since the region of the frame portion 101 covered with the transparent resin layer 17 has no openings, thus having a substantially greater thickness and forming a large stepped portion, thus being subject to peeling.

In the case of the electromagnetic wave shielding material 1 according to the present invention, since the transparent resin layer 17 is embedded in the openings 103a, 105a of the mesh portion 103 and the transparent resin layer anchoring portion 105, respectively, a significantly larger physical anchoring effect can be obtained. In addition, a synergistic effect including an effect of enhancing the adhesiveness between the transparent resin layer 17 and the adhesive layer 13 or transparent substrate 11 can also be obtained, so that the peeling between the transparent resin layer 17 and the electromagnetic wave shielding layer 15 can be securely prevented.

Namely, in the present invention, as shown in FIG. 3, the mesh portion 103 is formed inside the inner periphery of the frame portion 107, and the transparent resin layer anchoring openings 105 are provided surrounding the outer periphery of the mesh portion 103, and the transparent resin layer 17 is then formed such that it fills and covers at least some of the openings 105a of the transparent resin layer anchoring portion 105. In this way, the adhesiveness between the layers and anchoring effect can be provided, so that the lifting or peeling between the layers constituting the shielding layer 15 can be prevented during the production process and the period of the actual time of use, thus obtaining excellent electromagnetic wave shielding properties due to the electromagnetic wave shielding layer 15, solving the problem of the uneven shape at the bottom face of the openings, as well as providing adequate transparency (visible light transmittance).

Also, the electromagnetic wave shielding material 1 of the present invention may be provided with a function, such as a function of absorbing a particular wavelength of visible light and/or near infrared light, antireflection function, hard coating function, antifouling function or anti-glaring function, or a layer having such a function on either of the front and rear faces and/or between the layers.

### (NIR Absorbing Layer)

Further, a light-absorbing agent for absorbing unneeded particular wavelengths of visible light and/or near infrared light may be added to the resin used for the transparent resin layer 17. By absorbing such particular wavelengths of visible light, unnaturalness or discomfort in reproducing natural colors of an image can be suppressed, thereby enhancing the visibility. Since the unneeded particular wavelengths in the visible light region emitted from the PDP often contain an orange color of a wavelength near 590 nm which is the spectrum of the neon atom, the light-absorbing agent for absorbing light near 590 nm is preferred. Particular wavelengths of the near infrared light include those within a range of about 780 to 1100 nm. It is preferred to absorb 80% or more of light in the wavelength band of 780 to 1100 nm. By absorbing such particular near infrared light, malfunction of a remotely operated equipment, which is placed around the image displaying device and actuated by near infrared light, can be prevented. As the near infrared light absorbing agent (hereinafter referred to as an NIR absorbing agent)>though being not limited in particular, a dye which has a sharp absorbing peak in the near infrared light region and a high transparency of the visible light region and no great absorbing peaks of particular wavelengths in the visible light region can be used. As the dye for absorbing unnecessary particular wavelengths in the visible light region, for example, polymethine-type dyes or porphyrin-type dyes can be mentioned. As the dye for absorbing the near infrared light, diimmonium-type compounds, cyanine-type compounds, phthalocyanine-type compounds or ditiol-type complexes can be mentioned. Alternatively, if the NIR absorbing agent is not added to the transparent resin layer 17, another layer containing the NIR agent (hereinafter, referred to as an NIR absorbing layer) may be provided on at least one of the surfaces.

### (Separate NIR Absorbing Layer)

A separate NIR absorbing layer may be provided on the side of the transparent resin layer 17 and/or on the opposite side, i.e., the side of the substrate 11. The NIR absorbing layer may be provided by laminating a commercially available film (e.g., trade name: No. 2832, produced by TOYOBOSEKI Co., Ltd.) containing the NIR absorbing agent on the transparent resin film 17, or coating the NIR absorbing agent contained in a binder thereon. As the binder, polyester resins, polyurethane resins, acryl resins, or other curable resins utilizing reactions of epoxy groups, acrylate groups, methacrylate groups or isocyanate groups such as the thermosetting type or ultraviolet curing type can be used.

(AR layer)

Though not shown, an antireflection layer (hereinafter referred to as an AR layer) is provided on the side of observers of the electromagnetic wave shielding material. The antireflection layer is adapted to prevent reflection of visible light, and various products including monolayer types and multilayer types are marketed. The monolayer type is formed by lamination of a low reflective index layer on the surface. The multilayer type is formed by laminating high reflective index layers and low reflective index layers alternately such that the low reflective index layer lies on the most front surface. As the high reflective index layer, niobium oxide, zirconium oxide and ITO can be mentioned, while magnesium fluoride and silicon oxide can be mentioned as the low reflective index layer. Additionally, a layer having a finely uneven surface adapted to diffusely reflect natural light may be provided.

### (Hard Coating Layer, Anti-Staining Layer, and Anti-Glaring Layer)

To the antireflection layer (AR) layer, a hard coating layer, anti-staining layer or anti-glaring layer may be provided. The hard coating layer has a hardness higher than the grade H as measured in the pencil hardness test of JIS-K 5400, and is formed by curing a polyfunctional acrylate, such as a polyester acrylate, urethane acrylate or epoxy acrylate, with heat or an ionizing radiation. The anti-staining layer is a water-repellent or oil-repellent coating and includes siloxane-type compounds and fluorinated alkyl-silyl compounds. The anti-glaring layer has a finely uneven surface and is adapted to diffusely reflect natural light.

### (Direct Attachment)

After providing the electromagnetic wave shielding layer formed in a mesh-like configuration on the observer side, and then providing at least a blackening treatment and an anticorrosive layer on the electromagnetic wave shielding layer as essential treatments, the electromagnetic wave shielding device can be attached directly to a PDP for example. Since the frame portion 107 is exposed on the surface, it is easy to lead to an electrode and provide an earth.

Since a black surface faces the observer side due to the blackening treatment applied to the frame portion 101, black color printing in a frame-like fashion provided on the front glass plate becomes unnecessary, leading to reduction of the process time and being advantageous in the cost.

### EXAMPLES

Hereinafter, the present invention will be described in further detail with reference to exemplary embodiments and comparative examples. However, it should be noted that the present invention is not limited to these embodiments.

### Example 1

As the electromagnetic wave shielding layer 15, an electrically conductive material formed by successively laminating a blackened layer of copper-cobalt particles with an average particle size of 0.3 μm and then a chromate-treated layer on an electrolytically produced copper foil with a thickness of 10 μm was used. After laminating the chromate-treated layer of copper-cobalt particles on the transparent substrate 11 composed of a biaxially oriented PET film A4300 (trade name of polyethylene terephthalate produced by TOYOBOSEKI Co., Ltd.) with a thickness of 100 μm using the two-part curable urethane-type adhesive 13, aging was performed for four days at 56° C. As the adhesive agent, a two-part curable urethane-type adhesive composed of a polyester urethane polyol as a basic material and a xylylene-diisocyanate as a curing agent was used in a coating amount such that the thickness after dried became 7 μm.

A line for producing shadow masks for color TVs which performs treatments from masking to etching using a continuous and belt-like material was used to form the mesh in accordance with the photolithography. First, a casein resist was coated on the whole surface of the electrically conductive material by flowing irrigation. The coated material was carried to the next station where the material was closely exposed to ultraviolet rays from a mercury lamp using an original plate with a pattern of a shape as described below. Carrying the materials in succession through each station, water development, hardening of the film, and then heating and baking were conducted.

The shape of the original pattern plate, as shown in FIG. 1, has a central region corresponding to a size, i.e., 42 type, of the screen 100 of an image displaying device (the widescreen type, corresponding to 42 inches of the diagonal length) which constitutes a mesh portion 103, wherein the mesh portion 103 is constructed with the square openings 103a arranged with a line width of 22 μm, a line distance (pitch) of 300 μm, and a bias angle of 49 degrees. In the region surrounding the periphery of the mesh portion 103, the openings 105a are arranged with a line interval of 210 μm, wherein the line width is continuously and gradually increased from 22 μm at the portion abutting on the mesh portion 103 toward the frame portion 107. As a result, the line width becomes 40 μm at the portion abutting on the frame portion 107 not having openings, and as such the opening ratio is decreased in a mode of gradation, thus forming the transparent resin layer anchoring portion 105 with a width of 5 mm. Furthermore, in the region surrounding the periphery of the transparent resin layer anchoring portion 105, the frame portion 107 with a width of 10 mm is provided.

Then, each processed material was carried to the next station where it was subjected to etching by spraying a solution of ferric chloride as an etching solution onto the surface so as to form the openings 103a, 105a. Carrying the materials in succession through each station, washing with water, removing of the resist, rewashing, and then heating and drying were conducted. A 22 μm resist pattern was used for forming the line width of the mesh portion 103 and the transparent resin layer anchoring portion 105, though the actually obtained line width after the etching was 12±5 μm (7 to 17 μm). The opening ratio of the mesh portion 103 was 92%. On the other hand, the opening ratio of the transparent resin layer anchoring portion 105 was 88% at the portion abutting on the mesh portion and 81% at the portion abutting on the frame portion.

Over the mesh portion 103 and the transparent resin layer anchoring portion 105, the transparent resin layer 17 was applied by the intermittent die coating method using a pattern having the same size and shape as the mesh portion 103 and the transparent resin layer anchoring portion 105 (i.e., a pattern surrounding the mesh portion and the periphery of the mesh portion with a margin of a 5 mm width). Thereafter, the obtained coated product was laminated on an SP-PET 20-BU (trade name of a mold-releasingly treated PET film produced by TOHCELLO Co., Ltd.) having a thickness of 50 μm, and the laminated product was then exposed to a 200 mJ/cm² dose of light (365 nm) using a high pressure mercury lamp.

As the transparent resin layer, a composition of 20 parts by weight of N-vinyl-2-pyrrolidone, 25 parts by weight of dicyclopentenyl acrylate, 52 parts by weight of oligoester acrylate (M-8060 produced by TOA GOSEI Co., Ltd.), 3 parts by weight of 1-hydroxycyclohexyl phenyl ketone (Irgacure 184 produced by Tiba Gigie Co., Ltd.) was used.

Thereafter, when peeling off the SP-PET20-BU, an electromagnetic wave material according to Example 1 could be obtained, in which the transparent resin layer 17 was applied to cover and smooth over the openings 103a of the mesh portion 103 and the openings 105a of the transparent resin layer anchoring portion 105, as shown in FIG. 3(A).

### Example 2

The composition of the transparent resin layer 17 was applied on the mesh portion 103 as well as on a 2.5 mm wide portion of the transparent resin layer anchoring portion 105 around the periphery of the mesh portion 103. Except these conditions, similar to the Example 1, an electromagnetic wave material according to Example 2 could be obtained, in which the transparent resin layer 17 was applied to cover and smooth over the openings 103a of the mesh portion 103 and a portion of the openings 105a of the transparent resin layer anchoring portion 105, as shown in FIG. 3(B). In this case, in the outer periphery of the transparent resin layer anchoring portion 105, the opening 105a remained still being exposed over a 2.5 mm width.

### Example 3

The composition of the transparent resin layer 17 was applied on the mesh portion 103 as well as on a total 5.5 mm wide portion including the transparent resin layer anchoring portion 105 and an outer surrounding portion. Except these conditions, similar to the Example 1, an electromagnetic wave material according to Example 3 could be obtained, in which the transparent resin layer 17 was applied to cover over the openings 103a of the mesh portion 103, the openings 105a of the transparent resin layer anchoring portion 105 as well as a 0.5 mm wide inner periphery (corresponding to 1.7 cycles of the openings) of the frame portion 107.

### Example 4

Except that each opening 105a of the transparent resin layer anchoring portion 105 was of a square shape, a 40 μm line width, a 300 μm line interval (pitch) and a 49-degree bias angle and the width of the transparent resin layer anchoring portion 105 was 5 mm, similar to the Example 1, an electromagnetic wave material according to Example 4 could be obtained, in which the transparent resin layer 17 was applied to cover and smooth over the openings 103a of the mesh portion 103 and the openings 105a of the transparent resin layer anchoring portion 105.

### Example 5

Except that each opening 105a of the transparent resin layer anchoring portion 105 is of a circular shape having the same opening ratio as in the Example 4, similar to the Example 1, an electromagnetic wave material according to Example 5 could be obtained, in which the transparent resin layer 17 was applied to cover and flatten over the openings 103a of the mesh portion 103 and the openings 105a of the transparent resin layer anchoring portion 105.

### Comparative Example 1

The shape of the pattern plate corresponds to a 42 type screen of an image displaying device which constitutes a mesh portion (the widescreen type, corresponding to 42 inches of the diagonal length), wherein the mesh portion 103 was constructed with the square openings arranged with a line width of 22 μm, a line interval (pitch) of 300 μm, and a bias angle of 49 degrees, and wherein the transparent resin layer anchoring portion 105 was not provided, but instead, a 15 mm wide frame region (frame portion) 101 directly surrounding the outer periphery of the mesh portion 103 and not having openings was provided. The coating pattern of the transparent resin layer 17, as shown in FIG. 4, included the mesh portion 103 and an inner peripheral 3.5 mm wide portion (corresponding to 11.7 cycles of the openings) of the frame portion 107 not having openings and surrounding the outer periphery of the mesh portion. Except these conditions, similar to the Example 1, an electromagnetic wave shielding material of Comparative example 1 was obtained.

### (Evaluation Method)

The evaluation was conducted for adhesiveness between the layers after a thermal shock test. The thermal shock test was carried out by repeating 100 times the conditions of at −40° C. for 1 hour and at 80° C. for 1 hour, followed by attachment of a Cellotape™, a 25 mm wide cellophane adhesive tape produced by NICHIBAN Co., Ltd. at 25° C. to sufficiently cover a region over the surface of the transparent resin layer and the frame portion not covered with the transparent resin, then forcibly peeling off the tape beginning from the portion not covered with the transparent resin.

Upon the peeling of the tape, the test sample including the transparent resin layer lifted or peeled away from the transparent substrate and/or electromagnetic wave shielding layer were considered as failure, while those not including the lifting or peeling were considered as passing the inspection. The total light transmittance, visibility and electromagnetic wave shielding ability were also measured.

The visibility was tested by putting each test sample on the front face of a PDP; WOOO (trade name, produced by HITACHI SEISAKUSHO CO., Ltd.), displaying the test pattern, a white color and then a black color, and observing them with eyes at a distance of 50 cm from the screen at a viewing angle within a range of from 0 to 80 degrees. The total light transmittance was measured at the mesh portion using a colorimeter HM150 (trade name, MURAKAMI SIKISAI Co., Ltd.) in accordance with JIS-K7361-1.

The electromagnetic wave shielding ability was measured in accordance with the KEC method (a measuring method of electromagnetic waves developed by a foundation, KANSAI-DENSI-KOUGYOU SINKOU CENTER).

### (Evaluation Results)

Either of the Examples 1 to 5 and Comparative example 1 presented the total light transmittance of 83.0% at the mesh portion, this value being considered adequate. Also, either of the Example 1 to 5 and Comparative example 1 exhibited a decrement factor of 30 to 60 dB for electromagnetic waves in the frequency range of 30 MHz to 1000 MHz, thus showing a sufficient electromagnetic wave shielding properties.

For the adhesiveness between the layers after the heat shock test, no lifting and peeling were found in the electromagnetic wave shielding materials of the Examples 1 to 5, thus being considered as passing the inspection, while the lifting or peeling could be found in the Comparative example 1, thus being considered as failure.

Finally, when each of the electromagnetic shielding materials of the Examples 1 to 5 having presented a good adhesiveness between the layers after the heat shock test was put on the front plate of a PDP display to evaluate the visibility while it displaying an image, each of the results presented a good visibility.

1. An electromagnetic wave shielding device disposed adjacent to the front surface of an image displaying device, comprising:
a transparent substrate;
an electromagnetic wave shielding layer provided on one surface of the transparent substrate and formed of an electrically conductive material; and
a transparent resin layer provided on the electromagnetic wave shielding layer;
wherein the electromagnetic wave shielding layer includes a mesh portion with a shape corresponding to a screen portion of the image displaying device, including openings arranged in large numbers, a transparent resin layer anchoring portion surrounding the mesh portion, including openings arranged in large numbers and having an opening ratio lower than that of the openings of the mesh portion, and a flat frame portion surrounding the transparent resin layer anchoring portion and not having openings; and
wherein the transparent resin layer is provided such that it extends over the surface of the mesh portion as well as over the surface of the transparent resin layer anchoring portion.

2. The electromagnetic wave shielding device according to claim 1, wherein
the transparent resin layer extends over the whole surface of the mesh portion as well as over the whole surface of the transparent resin layer anchoring portion and also covers an inner end portion of the frame portion.

3. The electromagnetic wave shielding device according to claim 1, wherein
the transparent resin layer extends over the whole surface of the mesh portion as well as over the whole surface of the transparent resin layer anchoring portion and terminates at the outer end portion of the transparent resin layer anchoring portion.

4. The electromagnetic wave shielding device according to claim 1, wherein
the transparent resin layer is provided to cover the whole surface of the mesh portion and an inner end portion of the transparent resin layer anchoring portion.

5. The electromagnetic wave shielding device according to claim 4, wherein the transparent resin layer extends over the whole surface of the mesh portion up to a middle portion of the transparent resin layer anchoring portion, but does not cover the outer periphery of the transparent resin layer anchoring portion.

6. The electromagnetic wave shielding device according to claim 1, wherein an adhesive layer is interposed between the transparent substrate and the electromagnetic wave shielding layer.
